(19) United States
(12) Patent Application Publication
(10) Pub. No.: US 2014/0111259 A1
(43) Pub. Date: Apr. 24, 2014

(54) POWER-ON RESET CIRCUIT

(71) Applicant: KEYSTONE SEMICONDUCTOR CORP., Hsinchu (TW)

(72) Inventor: Chao-Sung Lin, Hsinchu (TW)

(73) Assignee: KEYSTONE SEMICONDUCTOR CORP., Hsinchu (TW)

(21) Appl. No.: 13/893,601

(22) Filed: May 14, 2013

(30) Foreign Application Priority Data
Oct. 24, 2012 (TW) 101139288

(51) Int. Cl. H03L 5/00

(52) U.S. Cl. CPC H03L 5/00
USPC 327/143

(57) ABSTRACT

A power-on reset circuit includes a power confirmation module and a reset signal generator. The power confirmation module receives a supply voltage and generates a reference voltage and a comparison voltage. A magnitude of the reference voltage rises a first time delay after receipt of the supply voltage, and a magnitude of the comparison voltage rises a second time delay after receipt of the supply voltage. The second time delay is greater than the first time delay. The power confirmation module further outputs a confirmation signal based on the reference voltage and the comparison voltage. The reset signal generator outputs a reset signal according to the confirmation signal.

### CROSS-REFERENCE TO RELATED APPLICATION

This application claims priority to Taiwanese Application No. 101139288, filed on Oct. 24, 2012.

### BACKGROUND OF THE INVENTION

1. Field of the Invention

The invention relates to a circuit, and more particularly to a power-on reset circuit for triggering initialization of internal circuits of a system.

2. Description of the Related Art

A power-on reset (POR) circuit is commonly applied to an integrated circuit of a microcontroller for providing a reset signal to initiate operation of the integrated circuit.

Referring to FIG. 1, a conventional power-on reset circuit 1 is shown to include a supply voltage divider 11, a reference voltage generator 12 and a comparator 13.

The supply voltage divider 11 divides a supply voltage Vdd to produce an enabling voltage.

The reference voltage generator 12 is used to output a reference voltage.

The comparator 13 is coupled to the supply voltage divider 11 to receive the enabling voltage, and is coupled to the reference voltage generator 12 to receive the reference voltage. The comparator 13 outputs a reset signal with a high logic level when the enabling voltage is greater than the reference voltage, and outputs the reset signal with a low logic level when the enabling voltage is lower than the reference voltage. The reset operation begins when the reset signal is at the low logic level, and ends when the reset signal is at the high logic level.

Referring to FIG. 1 and FIG. 2, from a timing diagram of the signals of the power-on reset circuit 1, it is apparent that the power-on reset circuit 1 has the following drawback: when the reference voltage rises later than the enabling voltage for a time delay t1 (which is later than the rise of the enabling voltage at time t0), an unwanted glitch may occur on the reset signal between time t0 and t1.

The unwanted glitch may result in operation of the backend signal processing system (not shown) prior to provision of the correct reset signal, so that the backend signal processing system may not be initiated from a pre-defined state, thereby causing unpredictable issues.

### SUMMARY OF THE INVENTION

Therefore, an object of the present invention is to provide a power-on reset circuit that can overcome the above drawback of the prior art.

According to the present invention, a power-on reset circuit comprises:

a power confirmation module disposed to receive a supply voltage and configured to generate a reference voltage and a comparison voltage, a magnitude of the reference voltage rising according to a magnitude of the supply voltage a first time delay after receipt of the supply voltage, a magnitude of the comparison voltage rising according to the magnitude of the supply voltage a second time delay after receipt of the supply voltage, the second time delay being greater than the first time delay, the power confirmation module being further configured to output a confirmation signal based on the reference voltage and the comparison voltage; and

a reset signal generator coupled to the power confirmation module to receive the confirmation signal therefrom and configured to output a reset signal according to the confirmation signal.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic diagram illustrating a conventional power-on reset circuit;

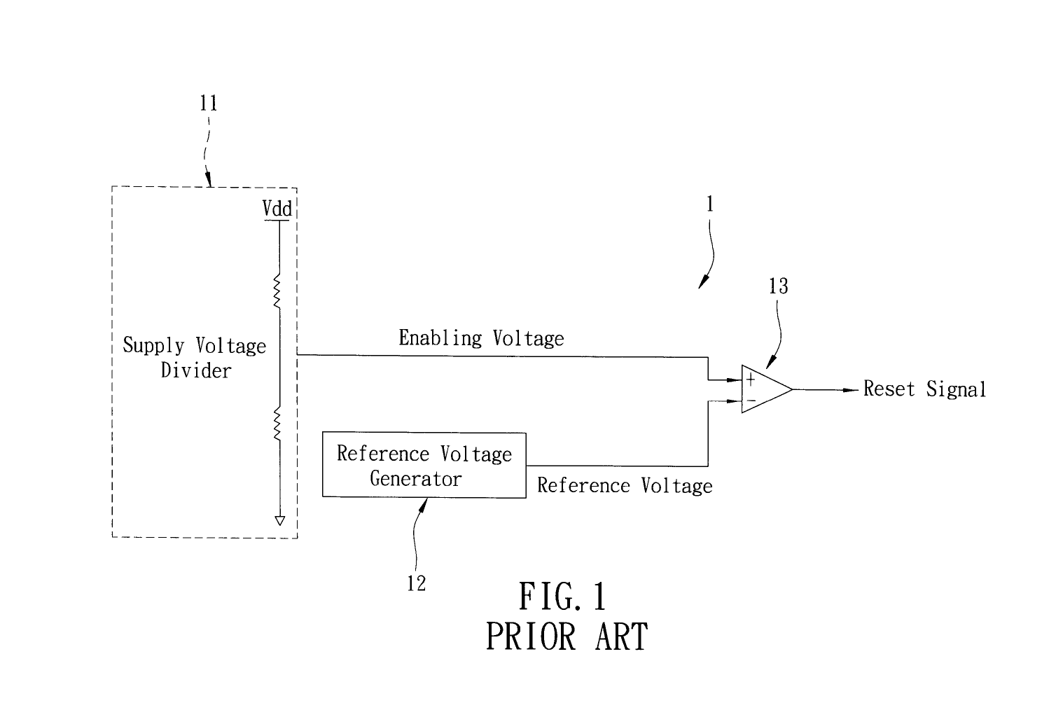

FIG. 2 is a timing diagram of signals of the conventional power-on reset circuit;

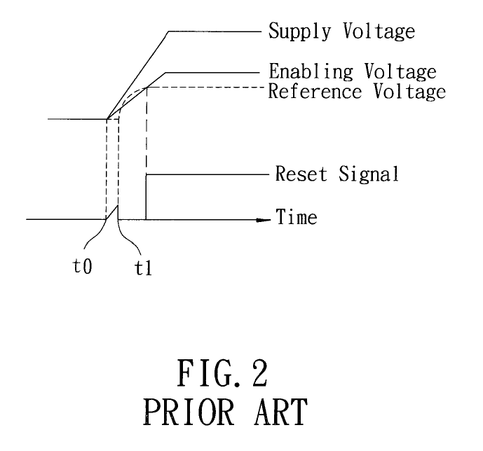

FIG. 3 is a schematic diagram illustrating a preferred embodiment of the power-on reset circuit according to the present invention;

FIG. 4 is a circuit diagram of a voltage generator of the preferred embodiment;

FIG. 5 is a circuit diagram of a comparator of the preferred embodiment;

FIG. 6 is a circuit diagram of an oscillator of the preferred embodiment;

FIG. 7 is a transfer curve of schmitt trigger of the oscillator of the preferred embodiment;

FIG. 8 is a timing diagram of signals of a Schmitt trigger of the preferred embodiment; and

FIG. 9 is a timing diagram of signals of the preferred embodiment.

### DETAILED DESCRIPTION OF THE PREFERRED EMBODIMENT

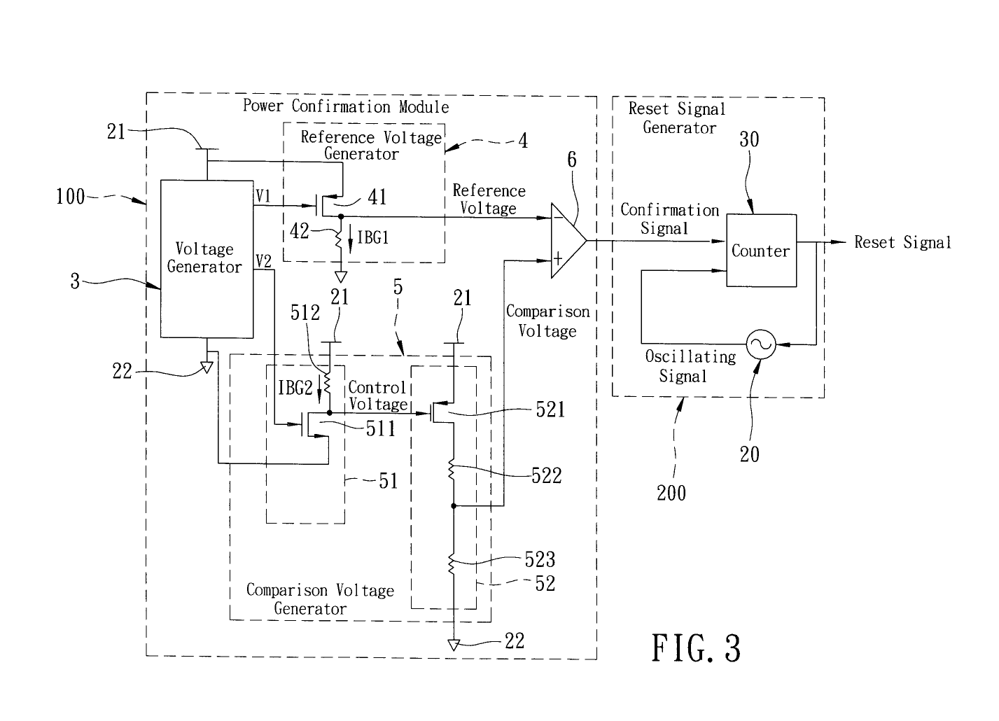

Referring to FIG. 3, the preferred embodiment of the power-on reset circuit according to this invention is shown to include a power confirmation module 100 and a reset signal generator 200.

The power confirmation module 100 is disposed to receive a supply voltage and generates a reference voltage and a comparison voltage. A magnitude of the reference voltage rises according to a magnitude of the supply voltage a first time delay after receipt of the supply voltage, and a magnitude of the comparison voltage rises according to the magnitude of the supply voltage a second time delay after receipt of the supply voltage. The second time delay is greater than the first time delay. The power confirmation module 100 outputs a confirmation signal based on the reference voltage and the comparison voltage.

The power confirmation module 100 has a supply voltage node 21 for receiving the supply voltage and a ground node 22 having a ground voltage, and includes a voltage generator 3, a reference voltage generator 4, a comparison voltage generator 5, and a comparator 6.

The voltage generator 3 is coupled to the supply voltage node 21 and the ground node 22 to receive the supply voltage, and generates, based on the supply voltage, first and second bias voltages V1, V2 each having a magnitude that rises with the magnitude of the supply voltage when the magnitude of the supply voltage is not greater than a supply threshold voltage value. After the magnitude of the supply voltage becomes greater than the supply threshold voltage value, a difference between the supply voltage and the first bias voltage V1 is substantially constant, and the second bias voltage V2 is substantially constant.

In detail, the voltage generator 3 generates a reference current having a magnitude that varies with the voltage difference between the magnitudes of the supply voltage and the first bias voltage V1, and to generate the second bias voltage V2 with the magnitude that varies with the magnitude of the reference current.

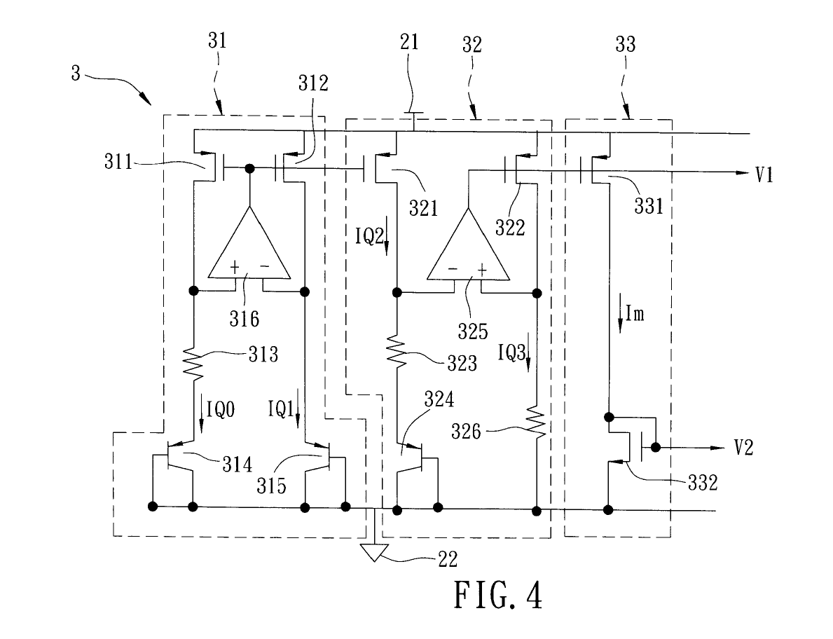

Referring to FIG. 4, the voltage generator 3 is a band gap bias current generator, and includes a first feedback unit 31, a second feedback unit 32, and a bias voltage generating unit 33.

The first feedback unit 31 generates a first current IQ1 having a magnitude that rises with ambient temperature.

The second feedback unit 32 is coupled to the first feedback unit 31 for generating a second current IQ2 mirrored from the first current IQ1, a third current IQ3 associated with the second current IQ2, and the first bias voltage V1 associated with a magnitude of the third current IQ3.

The bias voltage generating unit 33 is coupled to the second feedback unit 32 for receiving the first bias voltage V1 therefrom and for generating the reference current Im mirrored from the third current IQ3, and the second bias voltage V2 that is based on the reference current Im.

The first feedback unit 31 includes transistors 311, 312, 314, 315, a resistor 313, and an amplifier 316. Each of the transistors 311, 312, 314, 315 has a first terminal, a second terminal, and a control terminal.

In this preferred embodiment, the transistors 311, 312 are p-type metal-oxide-semiconductor field effect transistors (P-MOSFET). For the P-MOSFET in this embodiment, the first terminal is a source terminal, the second terminal is a drain terminal, and the control terminal is a gate terminal. The transistors 314, 315 are PNP bipolar junction transistors (BJT). For the PNP BJT in this embodiment, the first terminal is an emitter terminal, the second terminal is a collector terminal, and the control terminal is a base terminal.

The first terminals of the transistors 311, 312 are coupled to the supply voltage node 21 to receive the supply voltage, and the control terminals of the transistors 311, 312 are coupled to each other. The amplifier 316 has a non-inverting input (+) coupled to the second terminal of the transistor 311, an inverting input (−) coupled to the second terminal of the transistor 312, and an output coupled to the control terminal of the transistor 311. The resistor 313 has a first terminal coupled to the second terminal of the transistor 311. The first terminal of the transistor 314 is coupled to the second terminal of the resistor 313. The first terminal of the transistor 315 is coupled to the inverting input of the amplifier 316. The second terminals and the control terminals of the transistors 314, 315 are coupled to the ground node 22.

In the preferred embodiment, since a ratio of width-to-length (W/L) ratios of the transistors 311, 312 is 1:1, a current IQ0 that flows from the second terminal of the transistor 311 to the first terminal of the transistor 314 and the first current IQ1 that flows from the second terminal of the transistor 312 to the first terminal of the transistor 315 have the same magnitude. Since the voltages at the non-inverting and inverting inputs (+), (−) of the amplifier 316 are substantially the same, it is known that Iq1=(KT/q)×ln(N)/R1, where Iq1 is the magnitude of the first current IQ1, K is the Boltzmann constant, T is the ambient temperature in Kelvin scale, q is the elementary charge (1.6×10⁻¹⁹ coulombs), N=AE (314)/AE (315), where AE (314) is an emitter area of the transistor 314, and AE (315) is an emitter area of the transistor 315, and R1 is a resistance of the resistor 313. From the equation, it is known that the magnitude of the first current IQ1 is proportional to the ambient temperature in Kelvin scale.

The second feedback unit 32 includes transistors 321, 322, 324, resistors 323, 326, and an amplifier 325.

In this embodiment, the transistors 321, 322 are P-MOSFETs, and the transistor 324 is a PNP BJT.

The first terminals of the transistors 321, 322 are coupled to the supply voltage node 21. The control terminal of the transistor 321 is coupled to the control terminal of the transistor 312. The amplifier 325 has a inverting input (−) coupled to the second terminal of the transistor 321, an non-inverting input (+) coupled to the second terminal of the transistor 322, and an output that is coupled to the control terminal of the transistor 322 and that outputs the first bias voltage V1. The resistor 323 has a first terminal coupled to the second terminal of the transistor 321, and a second terminal. The first terminal of the transistor 324 is coupled to the second terminal of the resistor 323, and the second terminal and the control terminal of the transistor 324 are coupled to the ground node 22. The resistor 326 has a first terminal coupled to the non-inverting input (+) of the amplifier 325, and a second terminal coupled to the ground node 22.

In the preferred embodiment, since a ratio of W/L ratios of the transistors 321, 312 is 1:1, the second current IQ2 that flows from the second terminal of the transistor 321 to the first terminal of the transistor 324 and the first current IQ1 have the same magnitude. Since the voltages at the non-inverting and inverting inputs (+), (−) of the amplifier 325 are substantially the same, it is known that a current IQ3 that flows from the second terminal of the transistor 322 to the first terminal of the resistor 326 has a magnitude Iq3=(Iq2×R2+VEB)/R3, where VEB is a voltage difference between the emitter terminal and the base terminal of the transistor 324, Iq2 is the magnitude of the second current IQ2, R2 is a resistance of the resistor 323, and R3 is a resistance of the resistor 326. From the equation, it is known that the magnitude of the third current IQ3 is associated with the magnitude of the second current IQ2 and the voltage difference VEB. Since the magnitude of the second current IQ2 is the same as that of the first current IQ1, the magnitude of the second current IQ2 is proportional to the ambient temperature. However, the magnitude of VEB is inversely proportional to the ambient temperature. Through adjustment of the resistance R2 of the resistor 323, a voltage between the first and second terminals of the resistor 326 can be independent of the ambient temperature and stable. That is, a temperature parameter of the third current IQ3 is inversely proportional to that of the resistor 326.

The bias voltage generating unit 33 includes transistors 331 and 332. The transistor 331 has a first terminal coupled to the supply voltage node 21 to receive the supply voltage, a second terminal, and a control terminal that is coupled to the control terminal of the transistor 322. The transistor 332 has a first terminal coupled to the second terminal of the transistor 331, a second terminal coupled to the ground node 22, and a control terminal that is coupled to the first terminal thereof and that outputs the second bias voltage V2. In this embodiment, the W/L ratio of the transistor 331 is the same as that of the transistor 322, so that the reference current Im has a same magnitude as the third current IQ3, and the temperature parameter of the reference current Im is inversely proportional to that of the resistor 326. Therefore, a voltage difference between the first bias voltage V1 and the supply voltage, and the second bias voltage V2 that are associated with the magnitude of the reference current Im are also inversely proportional to the temperature parameter of the resistor 326.

Referring back to FIG. 3, the reference voltage generator 4 receives the supply voltage, and is coupled to the voltage generator 3 for receiving the first bias voltage V1 therefrom. The reference voltage generator 4 outputs the reference voltage having a magnitude that rises until the magnitude of the supply voltage becomes greater than the supply threshold voltage value, and that does not vary with the ambient temperature and is substantially non-varying when the magnitude of the supply voltage is greater than the supply threshold voltage value.

In this embodiment, the reference voltage generator 4 includes a transistor 41 and a resistor 42.

The transistor 41 has a first terminal coupled to the supply voltage node 21 to receive the supply voltage, a second terminal, and a control terminal coupled to the transistor 331 (see FIG. 4) of the voltage generator 3 for receiving the first bias voltage V1 therefrom. The transistor 41 generates a current IBG1 that flows through the second terminal thereof and that has a magnitude rising with the voltage difference between the magnitudes of the first bias voltage V1 and the supply voltage when the voltage difference between the magnitudes of the first bias voltage V1 and the supply voltage becomes greater than a first threshold voltage value.

The resistor 42 has a first terminal coupled to the second terminal of the transistor 41 for receiving the current IBG1 therefrom, and a second terminal coupled to the ground node 22. The magnitude of the reference voltage, which is outputted at the first terminal of the resistor 42, is proportional to the magnitude of the current IBG1 from the transistor 41.

In the preferred embodiment, the transistor 41 is a P-MOSFET, and the first threshold voltage value is a threshold voltage value of the transistor 41.

When the supply voltage is smaller than the supply threshold voltage value and is rising, the voltage difference between the magnitudes of the supply voltage and the first bias voltage V1 also rises, resulting in rise of the current IBG1. The reference voltage has a magnitude Vref=Ibg1×R1, where Ibg1 is a magnitude of the current IBG1, and R1 is a resistance of the resistor 42. When the magnitude of the supply voltage is smaller than the supply threshold voltage value, since the magnitude of the current IBG1 rises with the difference between the magnitudes of the supply voltage and the first bias voltage V1, which is inversely proportional to the temperature parameter of the resistor 326, the magnitude of the current IBG1 is inversely proportional to the temperature parameter of the resistor 326. Since the resistance R1 of the resistor 42 and the resistance R3 of the resistor 326 substantially have the same temperature parameter, the magnitude of the reference voltage Vref=(Iq2×R2+VEB)×(R1/R3) does not vary with ambient temperature.

The comparison voltage generator 5 receives the supply voltage and is coupled to the voltage generator 3 for receiving the second bias voltage V2 therefrom. The comparison voltage generator 5 outputs the comparison voltage having the magnitude that is one of a first voltage level and a second voltage level based on the magnitude of the second bias voltage. The first voltage level is dependent on the magnitude of the supply voltage, and the second voltage level is independent of the magnitude of the supply voltage.

In detail, the comparison voltage generator 5 includes a control voltage generating unit 51 and a comparison voltage generating unit 52.

The control voltage generating unit 51 includes a transistor 511 and a resistor 512.

The transistor 511 has a first terminal, a second terminal coupled to the ground node 22, and a control terminal coupled to the voltage generator 3 for receiving the second bias voltage V2 therefrom. The resistor 512 has a first terminal that receives the supply voltage, and a second terminal coupled to the first terminal of the transistor 511, so as to generate a current IBG2 that has a magnitude rising with the magnitude of the second bias voltage V2 after the magnitude of the second bias voltage V2 becomes greater than a second threshold voltage value, and that flows from the first terminal to the second terminal of the transistor 511, to thereby enable output of a control voltage having a magnitude varying with the magnitude of the second bias voltage V2 at the second terminal of the resistor 512 when the magnitude of the second bias voltage V2 becomes greater than the second threshold voltage value.

In the preferred embodiment, the transistor 511 is an N-MOSFET. For the N-MOSFET in this embodiment, the first terminal is a drain terminal, the second terminal is a source terminal, and the control terminal is a gate terminal. The second threshold voltage value is a threshold voltage value of the transistor 511. The second bias voltage V2 rises with the supply voltage, the current IBG2 that flows through the resistor 512 becomes greater, and the control voltage outputted at the second terminal of the resistor 512 has a magnitude Vctr1=Vdd−Ibg2×R2, where Vdd is the magnitude of the supply voltage, Ibg2 is the magnitude of the current IBG2, and R2 is a resistance of the resistor 512.

The comparison voltage generating unit 52 receives the supply voltage and is coupled to the ground node 22. The comparison voltage generating unit 52 is further coupled to the control voltage generating unit 51 for receiving the control voltage therefrom, and outputs the comparison voltage having the magnitude that is one of the first voltage level and the second voltage level based on a difference between the magnitudes of the supply voltage and the control voltage. The first voltage level is at a divided voltage of the supply voltage, and the second voltage level is at a voltage of the ground node 22.

The comparison voltage generating unit 52 includes a switch 521 and resistors 522, 523. In this preferred embodiment, the switch 521 is a P-MOSFET, and conduction of the switch 521 is controlled by the voltage difference between the control terminal and the first terminal of the switch 521.

The switch 521 has a first terminal that receives the supply voltage, a second terminal, and a control terminal coupled to the control voltage generating unit 51 for receiving the control voltage therefrom. The switch 521 is controlled by the control voltage to make or break electrical connection between the first and second terminals thereof.

The resistor 522 has a first terminal coupled to the second terminal of the switch 521, and a second terminal.

The resistor 523 has a first terminal coupled to the second terminal of the resistor 522, and a second terminal coupled to the ground node 22.

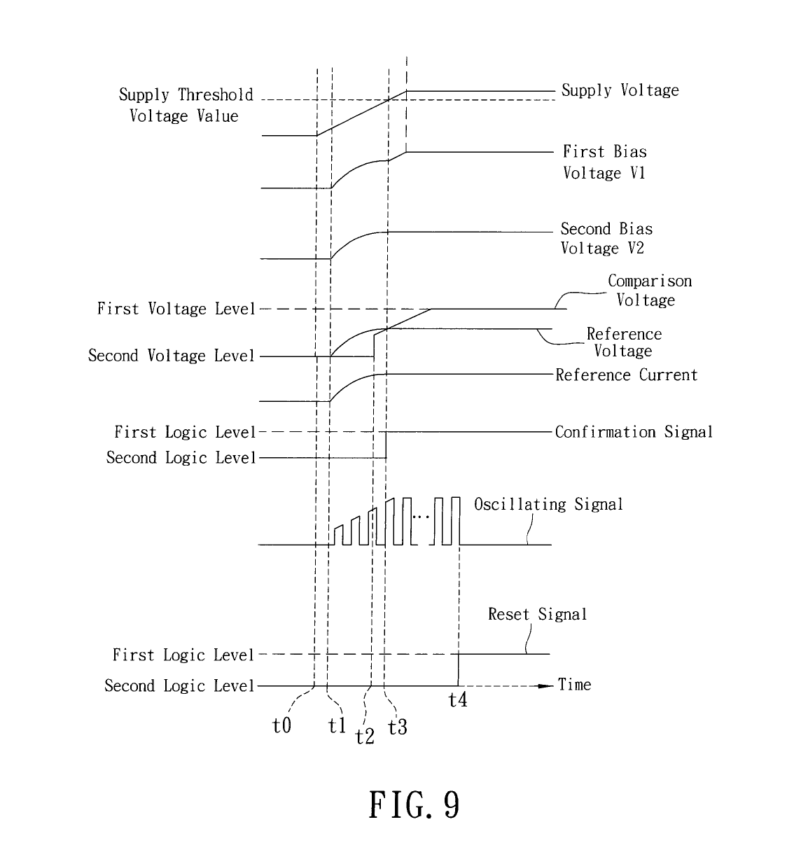

The comparison voltage generating unit 52 outputs the comparison voltage at the first terminal of the resistor 523. The comparison voltage has the magnitude rising with the magnitude of the supply voltage after a voltage difference between the control terminal of the switch 521 and the supply voltage at the first terminal of the switch 521 becomes greater than a third threshold voltage value (at the time t2 shown in FIG. 9), where the third threshold voltage value is a threshold voltage of the switch 521.

When the voltage difference between the control terminal and the first terminal of the switch 521 Vsw=Vdd−Vctr1=Vdd−(Vdd−Ibg2×R2)=Ibg2×R2 exceeds the third threshold voltage value, the switch 521 conducts, and the resistors 522, 523 form a voltage dividing circuit corresponding to the supply voltage, resulting in the comparison voltage having the first voltage level Vdd_sen=Vdd×R4/(R3+R4), where R3 is a resistance of the resistor 522, and R4 is a resistance of the resistor 523. On the other hand, when the voltage difference Vsw is smaller than the third threshold voltage value, the switch 521 does not conduct, and the comparison voltage has the second voltage level Vss_sen=Vss=0 since the resistor 523 is coupled to the ground node 22, where Vss is a voltage magnitude of the ground node 22.

In other words, it is only when the supply voltage has a sufficient magnitude, such as 70% of the supply voltage in a stable state, that each of the reference current Im, the voltage difference between the supply voltage and the first bias voltage V1, and the second bias voltage V2 will have a sufficient magnitude to generate the currents IBG1 and IBG2 with sufficient magnitude. Moreover, it is only when the current IBG2 has a sufficient magnitude that the voltage difference Vsw=Ibg×R2 will be sufficiently large to allow the comparison voltage generating unit 52 to output the comparison voltage with the first voltage level, which means that the voltage generator 3 is already in a stable state, and the reference voltage and the comparison voltage that are associated with the voltage generator 3 are stable and suitable for comparison. On the other hand, when the supply voltage is not large enough, such as being lower than 70% of the supply voltage in the stable state, the comparison voltage generator 5 outputs the comparison voltage with the second voltage level (0V).

The comparator 6 is coupled to the reference voltage generator 4 and the comparison voltage generator 5 for receiving the reference voltage and the comparison voltage therefrom, and outputs the confirmation signal corresponding to a result of comparison between the magnitudes of the reference voltage and the comparison voltage. In detail, when the comparison voltage has the first voltage level (at the divided voltage of the supply voltage) and is greater than the reference voltage, the confirmation signal is outputted with a first logic level (high logic level). On the other hand, when the confirmation voltage has the second voltage level, the confirmation signal is outputted with a second logic level (low logic level). That is, the preferred embodiment ensures that, when the confirmation signal has the first logic level, the magnitude of the supply voltage is already greater than a certain value that is based on the reference voltage and a voltage dividing ratio of the comparison voltage. For example, when the voltage dividing ratio of the comparison voltage is 0.5 and the magnitude of the reference voltage is 1.2 V at the stable state, the confirmation signal outputted by the power confirmation module 100 has the first logic level only when the supply voltage is greater than 2.4 V. Otherwise, the confirmation signal will have the second logic level. In addition, since the reference voltage does not vary with the ambient temperature, the supply voltage may be detected more precisely.

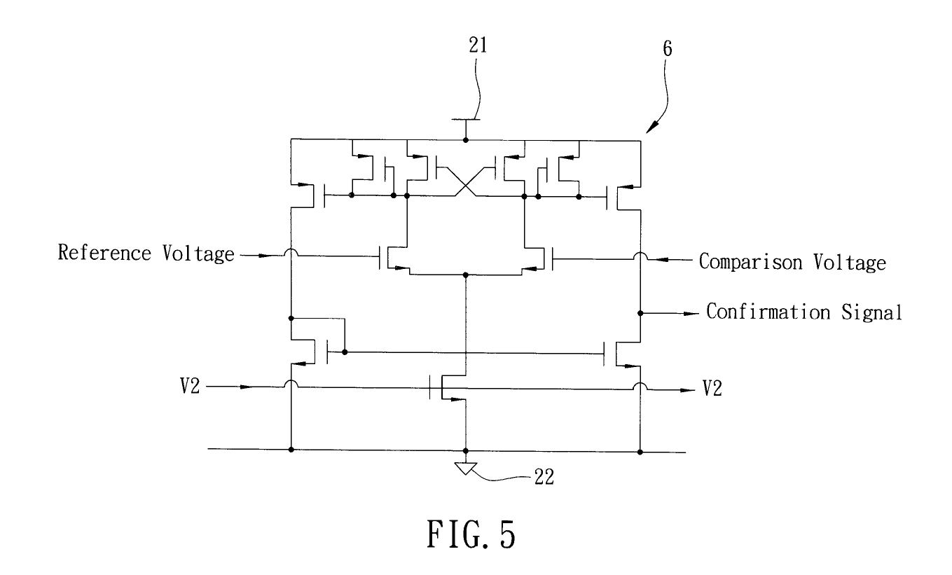

In the preferred embodiment, the comparator 6 is a hysteresis comparator as shown in FIG. 5.

Since the comparison voltage is relevant to the magnitude of the second bias voltage V2, which is associated with the magnitude of the supply voltage, the switch 521 does not conduct before the time t2 (i.e., the supply voltage is not sufficiently large, such as not reaching 70% of the supply voltage in the stable state), and the magnitude of the comparison voltage is 0V (the voltage magnitude of the ground node 22). At this time, since the comparator 6 outputs the confirmation signal based on comparison result of the magnitudes of the ground node 22 and the reference voltage, the confirmation signal will have the second logic level (low logic level), to thereby prevent the glitch commonly encountered in the prior art.

The reset signal generator 200 is coupled to the power confirmation module 100 to receive the confirmation signal therefrom and is configured to output a reset signal according to the confirmation signal.

In this embodiment, the reset signal generator 200 includes an oscillator 20 and a counter 30.

The counter 30 is coupled to the comparator 6 of the power confirmation module 100 for receiving the confirmation signal therefrom, and is coupled to the oscillator 20 for receiving an oscillating signal therefrom. The reset signal is at the low logic level when the confirmation signal is at the low logic level. The counter 30 is triggered by level transition of the confirmation signal to begin a counting operation, and outputs the reset signal with a high logic level that indicates stop of a reset status when a number of cycles of the oscillating signal counted during the counting operation reaches a predetermined value (such as 1638).

The oscillator 20 receives the supply voltage, and receives the reset signal from the counter 30. The oscillator 20 starts output of the oscillating signal upon receipt of the supply voltage, and stops output of the oscillating signal upon receipt of the reset signal to thereby reduce power consumption.

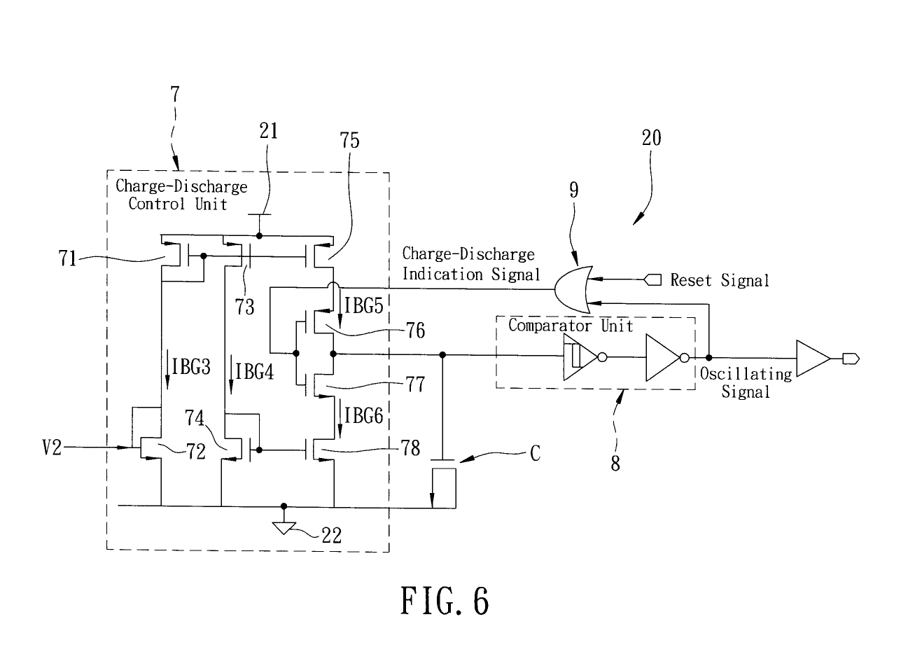

Referring to FIG. 6, the oscillator 20 includes a capacitor C, a charge-discharge control unit 7, a comparator unit 8 and an OR logic gate 9.

The capacitor C has a first terminal coupled to the ground node 22, and a second terminal. In this embodiment, the capacitor C is an N-MOSFET having electrically connected source and drain terminals to serve as the first terminal of the capacitor C, and a gate terminal to serve as the second terminal of the capacitor C.

The charge-discharge control unit 7 is coupled to the second terminal of the capacitor C, and receives a charge-discharge indication signal having one of the first and second logic levels from the OR logic gate 9. The charge-discharge control unit 7 discharges the capacitor C when the charge-discharge indication signal has the first logic level, and charges the capacitor C when the charge-discharge indication signal has the second logic level.

The charge-discharge control unit 7 includes transistors 71˜78. In the preferred embodiment, the transistors 71, 73, 75 and 76 are P-MOSFETs, and the transistors 72, 74, 77 and 78 are N-MOSFETs.

The transistor 71 has a first terminal receiving the supply voltage, and electrically connected second and control terminals. The transistor 72 has first and control terminals coupled to the voltage generator 3 and the second terminal of the transistor 71, and a second terminal coupled to the ground node 22. The transistor 72 receives the second bias voltage V2 at the control terminal thereof, and produces a current IBG3 associated with the magnitude of the second bias voltage V2 at the first terminal of the transistor 72.

The transistor 73 has a first terminal coupled to the first terminal of the transistor 71, a second terminal, and a control terminal coupled to the control terminal of the transistor 71. The transistor 74 has first and control terminals coupled to the second terminal of the transistor 73, and a second terminal coupled to the second terminal of the transistor 72. Since the first and control terminals of the transistor 73 are respectively coupled to the first and control terminals of the transistor 71, the current IBG3 is mirrored to the second terminal of the transistor 73, to thereby produce a current IBG4 having a magnitude associated with the current IBG3.

The transistor 75 has a first terminal coupled to the first terminal of the transistor 73, a second terminal, and a control terminal coupled to the control terminal of the transistor 73. The transistor 76 has a first terminal coupled to the second terminal of the transistor 75, a second terminal coupled to the second terminal of the capacitor C, and a control terminal coupled to the output of the OR gate 9 for receiving the charge-discharge indication signal therefrom. The transistor 77 has a first terminal coupled to the second terminal of the transistor 76, a second terminal, and a control terminal coupled to the control terminal of the transistor 76. The transistor 78 has a first terminal coupled to the second terminal of the transistor 77, a second terminal coupled to the second terminal of the transistor 74, and a control terminal coupled to the control terminal of the transistor 74.

Since the first and control terminals of the transistor 75 are respectively coupled to the first and control terminals of the transistor 73, the current IBG4 is mirrored to the second terminal of the transistor 75, to thereby produce a current IBG5 having a magnitude associated with the current IBG4. Since the second and control terminals of the transistor 78 are respectively coupled to the second and control terminals of the transistor 74, the current IBG4 is mirrored to the first terminal of the transistor 78, to thereby produce a current IBG6 having a magnitude associated with the current IBG4.

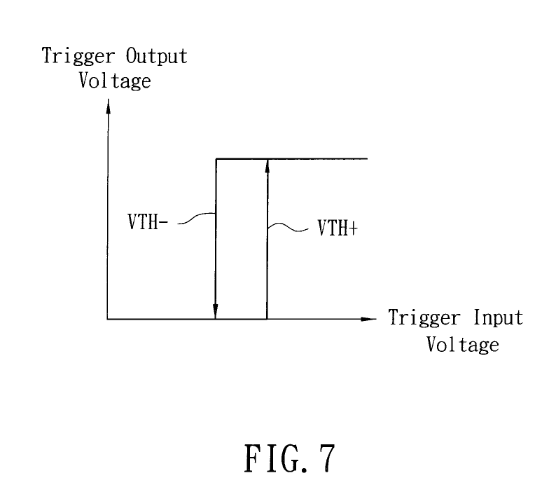

Referring to FIGS. 6 to 8, the comparator unit 8 is coupled to the second terminal of the capacitor C for detecting a capacitor voltage thereof, and outputs the oscillating signal having one of the first and second logic levels based on the capacitor voltage. When the capacitor C is discharged from a fully-charged state, the oscillating signal transitions from the first logic level (high logic level) to the second logic level (low logic level). When the capacitor C is charged from a discharged state, the oscillating signal transitions from the second logic level (low logic level) to the first logic level (high logic level). In the preferred embodiment, the comparator unit 8 includes two inverters coupled in series, and one of the inverters is a Schmitt trigger, which has a positive inverting threshold VTH+ and a negative inverting threshold VTH−, as shown in FIG. 7.

The OR logic gate 9 has a first input coupled to the counter 30 (see FIG. 3) for receiving the reset signal therefrom, a second input coupled to the comparator unit 8 for receiving the oscillating signal therefrom, and an output coupled to the charge-discharge control unit 7 for outputting the charge-discharge indication signal thereto.

When the supply voltage node 21 begins to provide the supply voltage, the reset signal has the second logic level (low logic level, which is 0V in this embodiment), the logic level of the charge-discharge indication signal outputted by the OR logic gate 9 is dependent on the logic level of the oscillating signal at the second terminal of the OR logic gate 9. At this time, since the capacitor Cis in the discharged state, the oscillating signal outputted by the comparator unit 8 has the low logic level. The charge-discharge indication signal which has the low logic level enables electrical connection between the first and second terminals of the transistor 76, which is a P-MOSFET, and breaks electrical connection between the first and second terminals of the transistor 77, which is an N-MOSFET. The current IBG5 at the second terminal of the transistor 75 thus charges the capacitor C.

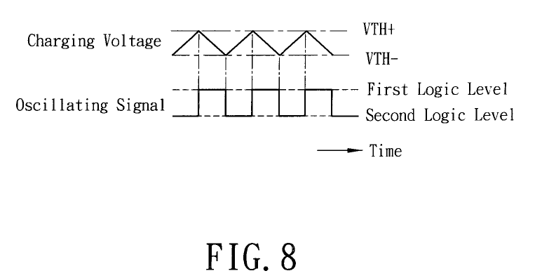

Referring to FIG. 8, when the capacitor C is fully-charged (i.e., the second terminal of the capacitor C has the voltage of VTH+), the comparator unit 8 outputs the oscillating signal that has the first logic level (high logic level), and the OR logic gate 9 thus outputs the charge-discharge indication signal with the first logic level. The charge-discharge indication signal with the first logic level enables electrical connection between the first and second terminals of the transistor 77, which is an N-MOSFET, and breaks electrical connection between the first and second terminals of the transistor 76, which is a P-MOSFET. The capacitor C is discharged through the transistors 77 and 78 to the ground node 22 until the second terminal of the capacitor C has the voltage of VTH−, and the oscillating signal thus transitions to the second logic level (low logic level). Based on the abovementioned charge-discharge operation on the capacitor C, the oscillating signal attributes between the first and second logic levels until the logic level of the reset signal becomes the first logic level (high logic level).

When the reset signal transitions from the second logic level to the first logic level, the charge-discharge indication signal outputted by the OR logic gate 9 always has the first logic level (high logic level), the transistor 76 is always cut-off, and the transistor 77 always conducts. Therefore, the capacitor C is always discharged, and the oscillator 20 does not output the oscillating signal to save power.

Referring to FIG. 9, a timing diagram of the signals of the preferred embodiment shows the supply voltage rises from the time t0, the reference voltage and the reference current Im (see FIG. 4) rise with the supply voltage from a time t1 after the time t0, and the comparison voltage rises with the supply voltage from a time t2 after the time t1. At the time t2, the reference voltage is almost stable and the comparison voltage is at 0V due to non-conduction of the switch 521 (see FIG. 3) before the time t2, so that the glitch described in the prior art will not occur in this embodiment before the time t2. Then, the comparison voltage keeps rising and exceeds the reference voltage at a time t3, and the confirmation signal thus has the first logic level. When the reset signal transitions at a time t4 after the time t3, which means that reset operation of the backend circuit (not shown) has been completed, the oscillator 20 stops output of the oscillating signal to save power.

To sum up, the preferred embodiment has the following advantages:

1. When magnitude of the supply voltage is lower than a certain value (such as 70% of the supply voltage in the stable state), that is, before the time t2, since the comparison voltage has the voltage of the ground node 22, and not a divided voltage of the supply voltage as in the prior art, the reset signal inevitably has the second logic level (low logic level), to thereby prevent glitch. Furthermore, after the time t2, the reference voltage has been stabilized for comparing with the comparison voltage, to thereby promote precision of the transition timing of the confirmation signal.

2. When the reset signal transitions from the second logic level to the first logic level, reset operation of the backend circuit (not shown) has been completed, and the oscillator 20 stops output of the oscillating signal for saving power.

3. The reset time period (a time period from the time t0 to the time t4) is adjustable through the predetermined value of the counter 30 for different backend circuits without requiring design change of the preferred embodiment.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A power-on reset circuit comprising:
a power confirmation module disposed to receive a supply voltage and configured to generate a reference voltage and a comparison voltage, a magnitude of the reference voltage rising according to a magnitude of the supply voltage a first time delay after receipt of the supply voltage, a magnitude of the comparison voltage rising according to the magnitude of the supply voltage a second time delay after receipt of the supply voltage, the second time delay being greater than the first time delay, said power confirmation module being further configured to output a confirmation signal based on the reference voltage and the comparison voltage; and
a reset signal generator coupled to said power confirmation module to receive the confirmation signal therefrom and configured to output a reset signal according to the confirmation signal.

2. The power-on reset circuit as claimed in claim 1, wherein said power confirmation module includes:
a voltage generator disposed to receive the supply voltage and configured to generate, based on the supply voltage, first and second bias voltages each having a magnitude that rises with the magnitude of the supply voltage when the magnitude of the supply voltage is not greater than a supply threshold voltage value;
a reference voltage generator disposed to receive the supply voltage, coupled to said voltage generator for receiving the first bias voltage therefrom, and configured to output the reference voltage when a voltage difference between the magnitudes of the supply voltage and the first bias voltage becomes greater than a first threshold voltage value;
a comparison voltage generator disposed to receive the supply voltage, coupled to said voltage generator for receiving the second bias voltage therefrom, and configured to output the comparison voltage having the magnitude that is one of a first voltage level and a second voltage level based on the magnitude of the second bias voltage, the first voltage level being dependent on the magnitude of the supply voltage, the second voltage level being independent of the magnitude of the supply voltage; and
a comparator coupled to said reference voltage generator and said comparison voltage generator for receiving the reference voltage and the comparison voltage therefrom, and configured to output the confirmation signal corresponding to a result of comparison between the magnitudes of the reference voltage and the comparison voltage.

3. The power-on reset circuit as claimed in claim 2, wherein said voltage generator is configured to generate a reference current having a magnitude that varies with the voltage difference between the magnitudes of the supply voltage and the first bias voltage, and to generate the second bias voltage with the magnitude that varies with the magnitude of the reference current.

4. The power-on reset circuit as claimed in claim 3, wherein said voltage generator includes:
a first feedback unit configured to generate a first current having a magnitude that rise with ambient temperature;
a second feedback unit coupled to said first feedback unit for generating a second current mirrored from the first current, a third current associated with the second current, and the first bias voltage associated with a magnitude of the third current; and
a bias voltage generating unit coupled to said second feedback unit for receiving the first bias voltage therefrom and for generating the reference current mirrored from the third current, and the second bias voltage that is based on the reference current.

5. The power-on reset circuit as claimed in claim 2, wherein the magnitude of the reference voltage outputted by said reference voltage generator rises until the magnitude of the supply voltage becomes greater than the supply threshold voltage value, and does not vary with ambient temperature and is substantially non-varying when the magnitude of the supply voltage is greater than the supply threshold voltage value.

6. The power-on reset circuit as claimed in claim 5, wherein said reference voltage generator includes:
a transistor having a first terminal disposed to receive the supply voltage, a second terminal, and a control terminal coupled to said voltage generator for receiving the first bias voltage therefrom, said transistor generating a current that flows through said second terminal thereof and that has a magnitude rising with the voltage difference between the magnitudes of the supply voltage and the first bias voltage; and
a resistor having a first terminal coupled to said second terminal of said transistor for receiving the current therefrom, and a second terminal coupled to a ground node;
wherein the magnitude of the reference voltage, which is outputted at said first terminal of said resistor, is proportional to the magnitude of the current from said transistor.

7. The power-on reset circuit as claimed in claim 2, wherein said comparison voltage generator includes:
a control voltage generating unit coupled to said voltage generator for receiving the second bias voltage therefrom, and configured to generate a control voltage having a magnitude varying with the magnitude of the second bias voltage when the magnitude of the second bias voltage becomes greater than a second threshold voltage value; and
a comparison voltage generating unit disposed to receive the supply voltage, coupled to a ground node, coupled to said control voltage generating unit for receiving the control voltage therefrom, and configured to output the comparison voltage having the magnitude that is one of the first voltage level and the second voltage level based on a difference between the magnitudes of the supply voltage and the control voltage, the first voltage level being at a divided voltage of the supply voltage, the second voltage level being at a voltage of the ground node.

8. The power-on reset circuit as claimed in claim 7, wherein said control voltage generating unit includes:
a transistor having a first terminal, a second terminal coupled to the ground node, and a control terminal coupled to said voltage generator for receiving the second bias voltage therefrom; and
a resistor having a first terminal that receives the supply voltage, and a second terminal coupled to said first terminal of said transistor, so as to generate a current that has a magnitude rising with the magnitude of the second bias voltage after the magnitude of the second bias voltage becomes greater than the second threshold voltage value, and that flows from said first terminal to said second terminal of said transistor, to thereby enable output of the control voltage at said second terminal of said resistor.

9. The power-on reset circuit as claimed in claim 7, wherein said comparison voltage generating unit includes:
a switch having a first terminal that is disposed to receive the supply voltage, a second terminal, and a control terminal coupled to said control voltage generating unit for receiving the control voltage therefrom, said switch being controlled by the control voltage to make or break electrical connection between said first and second terminals thereof;
a first resistor having a first terminal coupled to said second terminal of said switch, and a second terminal; and
a second resistor having a first terminal coupled to said second terminal of said first resistor, and a second terminal coupled to the ground node;
said comparison voltage generating unit outputting the comparison voltage at said first terminal of said second resistor, the comparison voltage having the magnitude rising with the magnitude of the supply voltage after a voltage difference between the control terminal of said switch and the supply voltage becomes greater than a third threshold voltage value.

10. The power-on reset circuit as claimed in claim 1, wherein said reset signal generator includes a counter coupled to said power confirmation module for receiving the confirmation signal therefrom, triggered by level transition of the confirmation signal to begin a counting operation, and operable to output the reset signal that indicates stop of a reset status when a count value generated during the counting operation reaches a predetermined value.

11. The power-on reset circuit as claimed in claim 10, wherein said reset signal generator further includes an oscillator for generating an oscillating signal, said counter being coupled to said oscillator for receiving the oscillating signal therefrom and generating the count value based on a number of cycles of the oscillating signal counted during the counting operation.

12. The power-on reset circuit as claimed in claim 11, wherein said oscillator is disposed to receive the supply voltage, is disposed to receive the reset signal from said counter, and is configured to start output of the oscillating signal upon receipt of the supply voltage, and to stop output of the oscillating signal upon receipt of the reset signal.

13. The power-on reset circuit as claimed in claim 11, wherein said oscillator includes:
a capacitor having a first terminal coupled to a ground node, and a second terminal;
a charge-discharge control unit coupled to said second terminal of said capacitor, and disposed to receive a charge-discharge indication signal having one of first and second logic levels, said charge-discharge control unit being configured to discharge said capacitor when the charge-discharge indication signal has the first logic level, and to charge said capacitor when the charge-discharge indication signal has the second logic level;
a comparator unit coupled to said second terminal of said capacitor for detecting a capacitor voltage thereof, and configured to output the oscillating signal having one of the first and second logic levels based on the capacitor voltage; and
an OR logic gate having a first input coupled to said counter for receiving the reset signal therefrom, a second input coupled to said comparator unit for receiving the oscillating signal therefrom, and an output coupled to said charge-discharge control unit for outputting the charge-discharge indication signal thereto.

14. The power-on reset circuit as claimed in claim 13, wherein said capacitor is a metal-oxide-semiconductor field-effect transistor (MOSFET) having electrically connected source and drain terminals to serve as said first terminal of said capacitor, and a gate terminal to serve as said second terminal of said capacitor.

15. The power-on reset circuit as claimed in claim 13, wherein said charge-discharge control unit includes:
a first transistor having a first terminal disposed to receive the supply voltage, and electrically connected second and control terminals;
a second transistor having first and control terminals coupled to said voltage generator and said second terminal of said first transistor, and a second terminal coupled to the ground node, said second transistor receiving the second bias voltage at said control terminal thereof;
a third transistor having a first terminal coupled to said first terminal of said first transistor, a second terminal, and a control terminal coupled to said control terminal of said first transistor;
a fourth transistor having first and control terminals coupled to said second terminal of said third transistor, and a second terminal coupled to said second terminal of said second transistor;
a fifth transistor having a first terminal coupled to said first terminal of said third transistor, a second terminal, and a control terminal coupled to said control terminal of said third transistor;
a sixth transistor having a first terminal coupled to said second terminal of said fifth transistor, a second terminal coupled to said second terminal of said capacitor, and a control terminal coupled to said output of said OR gate for receiving the charge-discharge indication signal therefrom;
a seventh transistor having a first terminal coupled to said second terminal of said sixth transistor, a second terminal, and a control terminal coupled to said control terminal of said sixth transistor; and
an eighth transistor having a first terminal coupled to said second terminal of said seventh transistor, a second terminal coupled to said second terminal of said fourth transistor, and a control terminal coupled to said control terminal of said fourth transistor.
